(19) United States
(12) Patent Application Publication
(10) Pub. No.: US 2023/0317436 A1
(43) Pub. Date: Oct. 5, 2023

(54) SUBSTRATE PROCESSING APPARATUS

(71) Applicant: Semes Co., Ltd., Cheonan-si (KR)

(72) Inventors: Dukhyun Son, Cheonan-si (KR); Jihun Kim, Pohang-si (KR); Yeonghun Wi, Busan-si (KR)

(73) Assignee: Semes Co., Ltd., Cheonan-si (KR)

(21) Appl. No.: 18/192,304

(22) Filed: Mar. 29, 2023

(30) Foreign Application Priority Data
Apr. 5, 2022 (KR) 10-2022-0042149

(51) Int. Cl. H01J 37/32; H01L 21/687; H01L 21/683

(52) U.S. Cl. CPC H01J 37/32807; H01L 21/68742; H01J 37/32715; H01L 21/68721; H01J 37/32642; H01L 21/6831; H01J 2237/3343; H01J 2237/024; H01J 2237/2007

(57) ABSTRACT

The disclosure provides a substrate processing apparatus including an electrostatic chuck disposed on a base to support a substrate, a focus ring disposed on the base to surround an outer circumference of the electrostatic chuck, and a lift pin configured to lift the focus ring, wherein the focus ring includes a lower ring and an upper ring disposed on the lower ring, the upper ring and/or the lower ring are configured to be simultaneously lifted according to a height of the lift pin, the lower ring includes an insertion groove, the upper ring includes a main body unit, a first protrusion extending downward from the main body unit and inserted into the insertion groove of the lower ring, and a second protrusion extending downward from the main body unit, contacting an outer circumference of the lower ring, and directly contacting the lift pin.

### CROSS-REFERENCE TO RELATED APPLICATION

This application is based on and claims priority under 35 U.S.C. § 119 to Korean Patent Application No. 10-2022-0042149, filed on Apr. 5, 2022, in the Korean Intellectual Property Office, the disclosure of which is incorporated by reference herein in its entirety.

### BACKGROUND

### 1. Field

The disclosure relates to a substrate processing apparatus, and more particularly, to a substrate processing apparatus including a focus ring.

### 2. Description of the Related Art

In a dry etching process, it is necessary to form plasma uniformly over an entire upper surface of a substrate. A focus ring is used to uniformly form plasma on the entire upper surface of the substrate. Because a portion of the focus ring is also exposed to plasma, a portion of the focus ring is etched. As a result, a height of an upper surface of the focus ring is lowered, and thus, plasma on the upper surface of the focus ring becomes non-uniform. Accordingly, a problem of reducing an etching accuracy of the substrate may occur.

### SUMMARY

Provided is a substrate processing apparatus capable of facilitating lifting and replacement of a focus ring.

Provided is a substrate processing apparatus capable of preventing change of an etch profile of a substrate due to wear of an upper ring according to wear of a focus ring.

The disclosure is not limited to the problems mentioned above, and other problems not mentioned will be clearly understood by those skilled in the art from the description below.

Additional aspects will be set forth in part in the description which follows and, in part, will be apparent from the description, or may be learned by practice of the presented embodiments of the disclosure.

According to an aspect of an embodiment, a substrate processing apparatus includes an electrostatic chuck disposed on a base to support a substrate, a focus ring disposed on the base to surround an outer circumference of the electrostatic chuck, and a lift pin configured to lift the focus ring, wherein the focus ring includes a lower ring and an upper ring disposed on the lower ring, and the upper ring is configured to be lifted or the upper ring and the lower ring are configured to be simultaneously lifted according to a height of the lift pin.

According to an aspect of an embodiment, a substrate processing apparatus includes an electrostatic chuck disposed on a base to support a substrate, a focus ring disposed on the base to surround an outer circumference of the electrostatic chuck, and a lift pin configured to lift the focus ring, wherein the focus ring includes a lower ring and an upper ring disposed on the lower ring, and the upper ring is configured to be lifted or the upper ring and the lower ring are configured to be simultaneously lifted according to a height of the lift pin, and the lower ring includes an insertion groove, wherein the upper ring includes a main body unit, a first protrusion extending downward from the main body unit and is inserted into the insertion groove of the lower ring, and a second protrusion extending downward from the main body unit, contacting an outer circumference of the lower ring, and directly contacting the lift pin.

According to an aspect of an embodiment, a substrate processing apparatus includes an electrostatic chuck disposed on a base to support a substrate, a focus ring disposed on the base to surround an outer circumference of the electrostatic chuck, and, a lift pin configured to lift the focus ring, wherein the focus ring includes a lower ring and an upper ring disposed on the lower ring, the upper ring is configured to be lifted or the upper ring and the lower ring are configured to be simultaneously lifted according to a height of the lift pin, the lift pin is configured to move up and down between a first height, a second height higher than the first height, and a third height higher than the second height, when the lift pin moves between the first height and the second height, the lower ring is configured to stop and the upper ring is configured to move up and down, when the lift pin moves between the second height and the third height, the lower ring and the upper ring are configured to simultaneously move up and down, when the lift pin is at a position lower than the first height, the lift pin is spaced apart from the upper ring and the lower ring, wherein the lower ring includes a main body unit having an insertion groove, and, an outer unit extending outward from the main body unit and contacting a second protrusion of the upper ring, wherein the upper ring includes a main body unit, a first protrusion extending downward from the main body unit and inserted into the insertion groove of the lower ring, and, the second protrusion extending downward from the main body unit, contacting an outer circumference of the lower ring, and directly contacting the lift pin.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a substrate processing apparatus according to an embodiment of the inventive concept;

FIG. 2 is a cross-sectional view showing a portion of a substrate processing apparatus according to an embodiment of the inventive concept;

FIG. 3 is a cross-sectional view of a portion of a substrate processing apparatus according to an embodiment of the inventive concept;

FIG. 4 is a cross-sectional view showing a portion of a substrate processing apparatus according to an embodiment of the inventive concept;

FIG. 5 is a cross-sectional view of a portion of a substrate processing apparatus according to an embodiment of the inventive concept;

FIG. 6 is a cross-sectional view of a portion of a substrate processing apparatus according to an embodiment of the inventive concept; and

FIG. 7 is a cross-sectional view of a portion of a substrate processing apparatus according to an embodiment of the inventive concept.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings. In the drawings, like reference numerals refer to like elements throughout, the descriptions thereof will not be repeated. Embodiments of the disclosure may be modified in various forms, and the scope of the inventive concept should not be construed as being limited to the following examples. This embodiment is provided to more completely explain the disclosure to those skilled in the art. Accordingly, the shapes of elements in the drawings are exaggerated and reduced to emphasize clearer description.

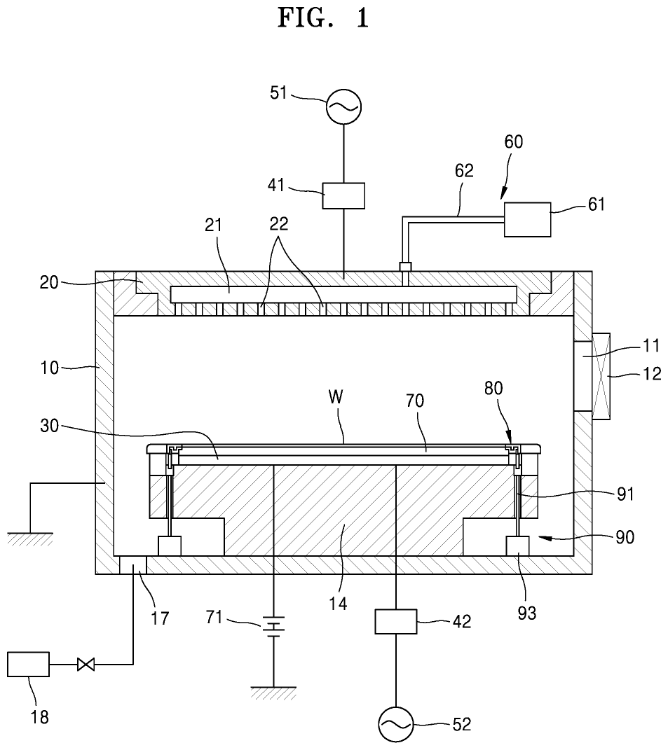

FIG. 1 is a schematic cross-sectional view of a substrate processing apparatus according to an embodiment.

As shown in FIG. 1, the substrate processing apparatus according to an embodiment includes a chamber 10, an upper electrode 20, a lower electrode 30, a gas supply unit 60, an electrostatic chuck 70, a focus ring 80, and a lift ring driving unit 90.

The chamber 10 provides a processing space for processing a substrate W using plasma. A film and/or a mask may be formed in a predetermined pattern on an upper surface of the substrate W. A passage 11 is formed on a side wall of the chamber 10. The substrate W may be introduced into the processing space inside the chamber 10 through the passage 11, and the substrate W may be taken out from the processing space inside the chamber 10. The passage 11 is configured to be opened and closed by a gate valve 12.

The upper electrode 20 is installed above the processing space of the chamber 10. The upper electrode 20 may be supported on the chamber 10. The upper electrode 20 includes a gas diffusion chamber 21 and a plurality of gas outlet holes 22 communicating with the gas diffusion chamber 21. Accordingly, a process gas introduced into the gas diffusion chamber 21 may be uniformly diffused in the gas diffusion chamber 21, and then, introduced into the processing space in the chamber 10 through the gas outlet hole 22.

A first high frequency power source 51 is electrically connected to the upper electrode 20 through a first matching unit 41. The first high frequency power source 51 applies first high frequency power having a frequency for generating plasma to the upper electrode 20. A process gas introduced into the processing space in the chamber 10 is converted into a plasma state by first high frequency power applied from the first high frequency power source 51. The process gas converted into a plasma state etches a specific film formed on the substrate W.

The lower electrode 30 is supported on a base 14 provided on a lower side of the chamber 10. The second high frequency power source 52 is electrically connected to the lower electrode 30 through a second matching unit 42. The second high frequency power source 52 applies a second high frequency power (high frequency power for bias) to the lower electrode 30.

The gas supply unit 60 includes a gas supplier 61 for supplying a process gas and a gas supply pipe 62 connecting the gas supplier 61 to the gas diffusion chamber 21 of the upper electrode 20. For example, the gas supplier 61 may include a plurality of open/close valves respectively connecting a plurality of gas sources and the gas supply pipe 62.

The electrostatic chuck 70 is installed on the lower electrode 30. A substrate W may be mounted on an upper surface of the electrostatic chuck 70. The electrostatic chuck 70 is connected to a DC power source 71. When power is applied from the DC power source 71 to the electrostatic chuck 70, an electrostatic attraction is generated between the substrate W and the electrostatic chuck 70. The substrate W may be electrostatically attracted to the upper surface of the electrostatic chuck 70 by the generated electrostatic attraction.

An outlet 17 is formed at a bottom of the chamber 10. The outlet 17 is connected to a vacuum pump 18, such as a dry pump. Thus, generated materials, such as polymers generated during a substrate treatment process may be discharged to the outside through the outlet 17.

The focus ring 80 may be disposed to surround an outer circumference of the substrate W. The focus ring 80 serves to improve the uniformity of the plasma treatment of the substrate W.

When high-frequency power is applied around the electrostatic chuck 70, an electric field is formed on an upper side of the substrate W, and the focus ring 80 further expands an area where the electric field is formed to place the substrate W at the center of the area where plasma is formed. Accordingly, the substrate W may be uniformly etched as a whole. In addition, in order to prevent a polymer compound generated during a substrate processing process from penetrating into the electrostatic chuck 70, the focus ring 80 covers and protects an edge of the electrostatic chuck 70.

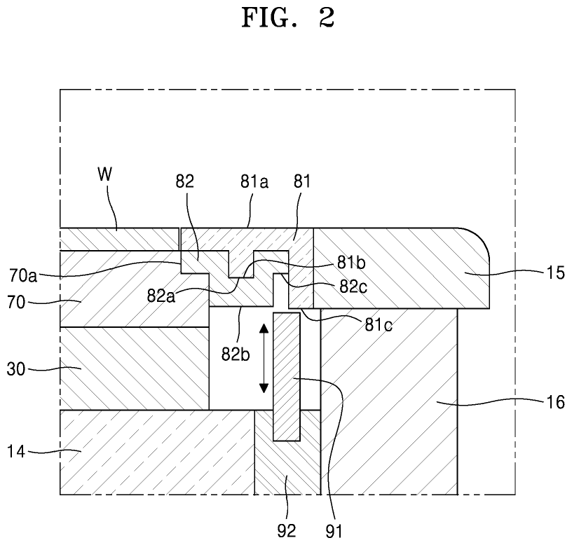

FIG. 2 is a cross-sectional view showing a portion of a substrate processing apparatus according to an embodiment.

Referring to FIGS. 1 and 2 together, the focus ring 80 is disposed on the base 14 to surround an outer circumference of the electrostatic chuck 70. The focus ring 80 includes an upper ring 81 and a lower ring 82 disposed between the upper ring 81 and the base 14. The upper ring 81 is located closer to the processing space within the chamber 10 than the lower ring 82.

According to one embodiment, the lower ring 82 includes an insertion groove 82a, and the upper ring 81 includes a main body unit 81a, a first protrusion 81b, and a second protrusion 81c.

The main body unit 81a of the upper ring 81 may be formed in a ring shape surrounding the substrate W with the substrate W as the center. For example, the main body unit 81a of the upper ring 81 may have a ring shape continuously extending along an outer circumference of the substrate W or an outer circumference of the electrostatic chuck 70. An inner side of the upper ring 81 toward the substrate W is configured to contact or face the circumference of the substrate W.

An upper surface of the upper ring 81 is disposed toward the processing space of the chamber 10, and the first protrusion 81b and the second protrusion 81c protrudes downward from the main body unit 81a of the upper ring 81 at a lower portion of the upper ring 81.

The first protrusion 81b is located at a lower central portion of the main body unit 81a of the upper ring 81 and is configured to be inserted into the insertion groove 82a formed in the lower ring 82. As a non-limiting example, the first protrusion 81b may have a rectangular cross section.

The second protrusion 81c is located outside the lower portion of the main body unit 81a of the upper ring 81. An inner side of the second protrusion 81c toward the substrate W may come into contact with an outer circumference of the outer unit 82c of the lower ring 82. At the same time, an outer side of the upper ring 81 may contact an inner surface of an outer ring 15 toward the substrate W. Accordingly, the second protrusion 81c may be formed in a shape penetrating between the outer ring 15 and the lower ring 82. A lower portion of the second protrusion 81c may be configured to contact an uppermost end of the lift pin 91 when the lift pin 91 is raised.

A main body unit 82b of the lower ring 82 has a ring shape surrounding the electrostatic chuck 70 and may be positioned below the upper ring 81.

The insertion groove 82a may be formed in a central portion of an upper surface of the lower ring 82. The insertion groove 82a may accommodate the first protrusion 81b of the upper ring 81. As the first protrusion 81b of the upper ring 81 is inserted into the insertion groove 82a of the lower ring 82, the lower ring 82 and the upper ring 81 may be coupled. As a non-limiting example, when the first protrusion 81b has a rectangular cross section, the insertion groove 82a may have an empty rectangular shape accommodating the first protrusion 81b.

The lower ring 82 may include the outer unit 82c formed on the main body unit 82b of the lower ring 82 in a direction away from the electrostatic chuck 70. The outer unit 82c may contact an inner side of the second protrusion 81c that extends outward from the main body unit 82b and faces the substrate W. In addition, the lowermost end of the outer unit 82c is configured to contact the uppermost end of the lift pin 91 when the lift pin 91 is raised.

A portion of the lower ring 82 in contact with the electrostatic chuck 70 is configured to be supported by a circumferential groove 70a of the electrostatic chuck 70. The circumferential groove 70a may be formed on an outer circumference of the electrostatic chuck 70 so that an inner portion of the main body unit 82b of the lower ring 82 is placed. The lower ring 82 may be located on the circumferential groove 70a and supported by the circumferential groove 70a.

When the upper ring 81 is raised by the lift pin 91 while the lower ring 82 is stopped, the uppermost end of the lift pin 91 may contact the lowermost end of the second protrusion 81c. When the upper ring 81 and the lower ring 82 are simultaneously lifted by the lift pin 91, the uppermost end of the lift pin 91 may contact the lowermost end of the second protrusion 81c of the upper ring 81 and the outer unit 82c of the lower ring 82.

In adjusting the position of the upper ring 81 with respect to the substrate W, fine adjustment is required when the upper ring 81 moves up and down. At this time, according to the embodiment of the disclosure, when only the upper ring 81 is lifted, the first protrusion 81b of the upper ring 81 is guided by the side of the lower ring 82 defining the insertion groove 82a and the second protruding portion 81c of the upper ring 81 is guided by the outer portion 82c and the outer ring 15 so that the first protrusion 81b and the second protruding portion 81c move up and down. Therefore, because the upper ring 81 moves up and down by being guided by a surrounding structure of the substrate processing apparatus, the lifting operation of the upper ring 81 may be stably implemented and a height adjustment of the upper ring 81 may be easily realized.

The lift ring driving unit 90 may include the lift pin 91 contacting the focus ring 80, a guide block 92 assisting the lifting of the lift pin 91, and a lift pin driver 93 that provides power for lifting the lift pin 91.

The lift pin 91 is configured to move up and down by the lift pin driver 93 located inside the chamber 10. As a non-limiting example of the lift pin driver 93, the lift pin driver 93 may include an actuator, such as a motor.

A guide block 92 may be positioned around the base 14. The guide block 92 may have a through hole in a length direction at its center so that the lift pin 91 passes through the through hole. The through hole of the guide block 92 is configured to smoothly move up and down the lift pin 91 while contacting a side of the lift pin 91 having a cylindrical shape. When the lift pin 91 moves up and down, the lift pin 91 may move up and down along a vertical component without moving along a horizontal component due to the guide block 92. Also, when the lift pin 91 supports the focus ring 80, bending of the lift pin 91 may be prevented.

The outer ring 15 may be located on an outer circumference of the focus ring 80. At the same time, the outer ring 15 may be arranged to contact an outside of the second protrusion 81c of the upper ring 81. The outer ring 15 assists the focus ring 80 so that the substrate W is located at the center of a region where plasma is formed. However, unlike the upper ring 81, the outer ring 15 is farther from the substrate W, the outer ring 15 is less worn by etching, thus, frequent replacement of the outer ring 15 is not required.

A bottom ring 16 supports a lower surface of the outer ring 15 at the lower end of the outer ring 15, and the bottom ring 16 may be located outside the guide block 92.

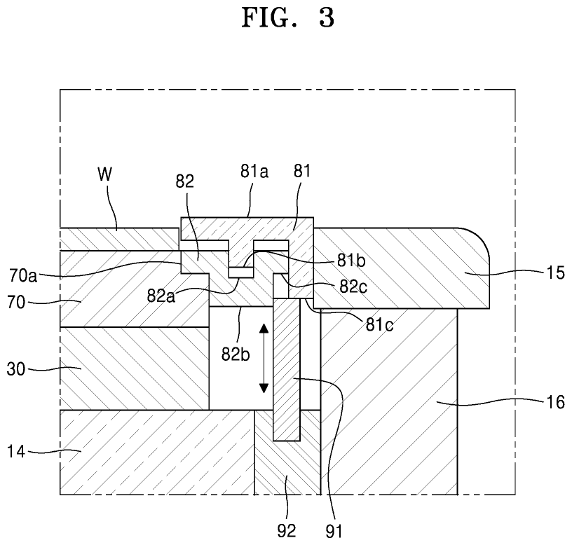

FIGS. 3, 4 and 5 are cross-sectional views of a substrate processing apparatus according to an embodiment. Hereinafter, a lifting operation of the focus ring 80 by the lift pin 91 will be described with reference to FIGS. 2 to 5.

Referring to FIG. 2, when the lift pin 91 descends, the lift pin 91 may not contact the upper ring 81 and the lower ring 82.

Referring to FIGS. 2 and 3, when the lift pin 91 rises, the uppermost end of the lift pin 91 may come into contact with a portion of the second protrusion 81c of the upper ring 81. A height of the lift pin 91 at the moment when the uppermost end of the lift pin 91 contacts a portion of the second protrusion 81c is referred to as a first height. Here, the height of the lift pin 91 means the vertical position of the uppermost end of the lift pin 91.

When the lift pin 91 rises while maintaining contact with the second protrusion 81c, the upper ring 81 may rise as the lift pin 91 rises. As the upper ring 81 rises, the first protrusion 81b may gradually come out of the insertion groove 82a. When the lift pin 91 continues to rise, the uppermost end of the lift pin 91 comes into contact with the outer unit 82c of the lower ring 82. A height of the lift pin 91 at the moment when the uppermost end of the lift pin 91 contacts the outer unit 82c of the lower ring 82 is referred to as a second height.

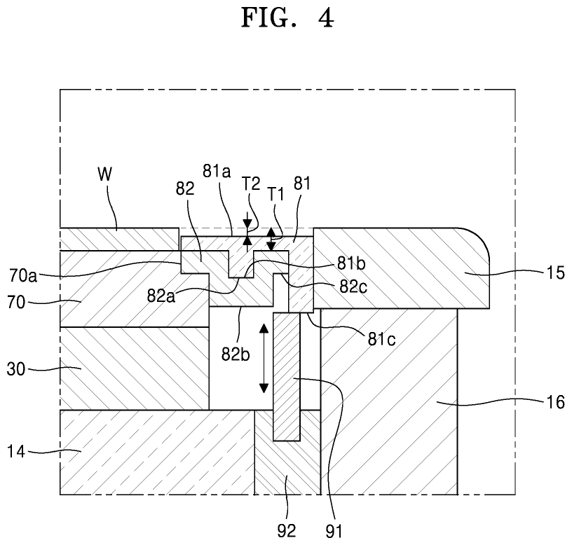

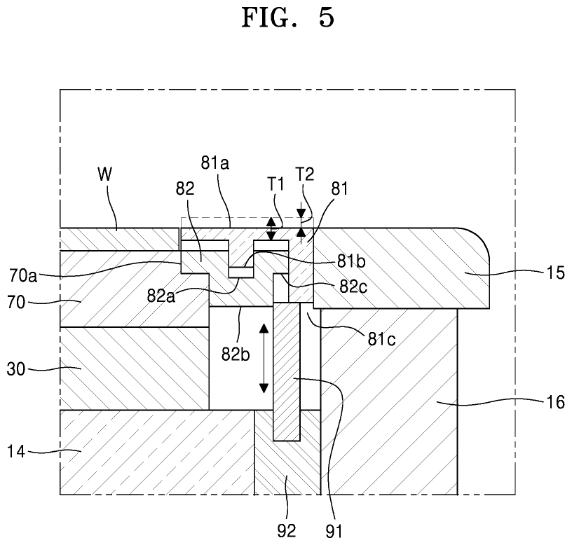

Referring to FIGS. 4 and 5, the lift pin 91 may rise while maintaining a state in which the uppermost end of the lift pin 91 is in contact with the outer unit 82c of the lower ring 82 and the second protrusion 81c of the upper ring 81. When the lifting of the lift pin 91 continues and the lifting ends, the height of the lift pin 91 at that time is referred to as a third height.

According to an embodiment, when the lift pin 91 is located at a height lower than the first height, the upper ring 81 and the lower ring 82 are not affected even if the lift pin 91 moves up and down. When the lift pin 91 is located between the first height and the second height, only the upper ring 81 may move up and down. When the lift pin 91 is located at a position higher than the second height, the upper ring 81 and the lower ring 82 may be simultaneously lifted.

In this way, according to an embodiment, it is possible to selectively move up and down of the upper ring 81 or the lower ring 82 constituting the focus ring 80 through the lifting of one lift pin 91. Therefore, because the substrate processing apparatus may be configured to be simple through the disclosure and the production of the substrate processing apparatus is easier, it is possible to increase productivity of a substrate processing apparatus.

The upper ring 81 and the lower ring 82 may include different materials from each other. For example, the upper ring 81 may include quartz, and the lower ring 82 may include silicon carbide (SiC).

When both the upper ring 81 and the lower ring 82 include silicon carbide, silicon carbide reacts with silicon (Si) during a substrate processing process, and thus, a foreign substance, such as black silicon is generated. The foreign substance may cause a decrease in the efficiency of the substrate processing process. When both the upper ring 81 and the lower ring 82 include quartz, the wear of the upper ring 81 and the lower ring 82 increases due to etching by plasma, and thus, there is a problem in that the replacement cycle of the upper ring 81 and the lower ring 82 is shortened.

On the other hand, as in the case when the upper ring 81 includes quartz and the lower ring 82 includes silicon carbide, the upper ring 81 may include a material that may reduce the generation of a foreign substance by reacting with plasma, and the lower ring 82 may include a material capable of reducing wear caused by plasma. In this case, the replacement cycle is longer than that of the focus ring unit including one material, thus, the process efficiency may be improved.

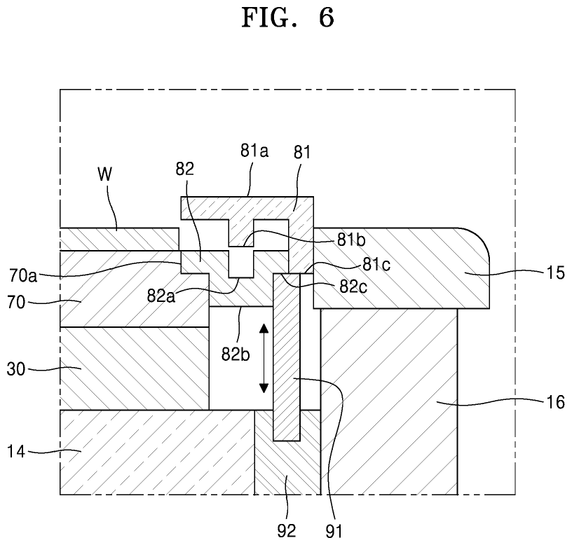

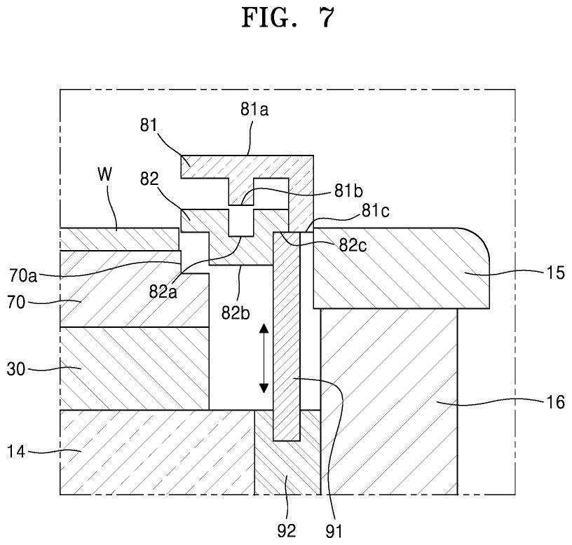

FIGS. 6 and 7 are cross-sectional views showing a substrate processing apparatus according to an embodiment.

Referring to FIGS. 6 and 7, the upper ring 81 is directly exposed to plasma during an etching process, and thus, is worn by plasma. As the process of processing a substrate using plasma proceeds, the upper ring 81 may be worn and a thickness T1 of the upper ring 81 may decrease. A distance from an upper surface of the upper ring 81 to a lower surface of the main body unit 81a of the upper ring 81 excluding the first protrusion 81b and the second protrusion 81c is referred to as the thickness T1 of the upper ring 81.

When the thickness T1 of the upper ring 81 decreases due to wear, a height of the upper surface of the upper ring 81 decreases based on the height of the upper surface of the substrate W. When the height of the upper surface of the upper ring 81 decreases while the height of the upper surface of the substrate W does not change, the plasma sheath changes. Accordingly, an incident angle of ions greatly fluctuates at an edge portion of the substrate W, which may cause an etching profile to be deformed at the edge portion of the substrate W.

As a method for preventing this phenomenon, a method of replacing the upper ring 81 may be considered. However, frequent replacement of the upper ring 81 reduces an operation rate of the substrate processing apparatus due to frequent interruption of the substrate processing process and causes cost increase due to consumption of the upper ring 81.

In the substrate processing apparatus according to an embodiment, the height of the upper surface of the upper ring 81 may be finely adjusted by raising the upper ring 81 according to the degree of wear of the upper ring 81. Referring to FIG. 6, the thickness T1 of an initial upper ring 81 may be reduced as much as the worn thickness T2 of the upper ring 81 due to etching. Referring to FIG. 7, the lift pin 91 may raise the upper ring 81 as much as the worn thickness T2 of the upper ring 81 from the first height which is a height of the lift pin 91 at the moment when the lift pin 91 contacts the second protrusion 81c. The height of the upper surface of the upper ring 81 may be adjusted to be constant with respect to the height of the upper surface of the substrate W by the elevation of the upper ring 81 by the worn thickness T2. For example, the lift pin 91 may adjust a vertical position of the upper ring 81 so that the upper surface of the upper ring 81 is positioned at the same vertical level as the upper surface of the substrate W. This adjustment is possible until the upper ring 81 is worn to a thickness required for replacement within a range of the thickness T1 of the initial upper ring 81.

As such, as an embodiment of the inventive concept, the height of the upper surface of the upper ring 81 with respect to the height of the upper surface of the substrate W may be maintained constant. Therefore, since the plasma sheath may be maintained constant, the etching profile of the substrate W may be maintained for a long time even when the upper ring 81 is worn. As the upper ring 81 may be used for a long time, the use cycle increases and the replacement cycle of the upper ring 81 may be increased. In addition, because the frequency of interruption of the etching process decreases as the number of replacements of the upper ring 81 decreases, the etching process may continue for a long time, thereby improving productivity. In addition, because the use cycle of the upper ring 81 increases and the number of replacements may be reduced, the replacement cost of the upper ring 81 may be reduced.

In the substrate processing apparatus according to an embodiment, when the wear of the upper ring 81 progresses to a significant level and replacement of the upper ring 81 is required, the lift pin 91 may rise within the range between the second height and the third height. When the lift pin 91 rises in a section between the second height and the third height, the upper ring 81 and the lower ring 82 may be simultaneously lifted by the lift pin 91. The upper ring 81 and the lower ring 82 raised at the same time may be replaced by a robot arm.

A substrate processing apparatus according to an embodiment includes a substrate processing apparatus having three or more lift pins 91 including lift pin 91. Three or more supporting points may be required to stably support a plane through the supporting points. Therefore, in order to stably lift the upper ring 81 or the lower ring 82, three or more lift pins 91 may be provided in the substrate processing apparatus. In addition, four or more lift pins 91 may be provided as needed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
an electrostatic chuck disposed on a base to support a substrate;
a focus ring disposed on the base to surround an outer circumference of the electrostatic chuck; and
a lift pin configured to lift the focus ring,
wherein the focus ring includes a lower ring and an upper ring disposed on the lower ring, and
the upper ring is configured to be lifted or the upper ring and the lower ring are configured to be simultaneously lifted according to a height of the lift pin.

2. The substrate processing apparatus of claim 1, wherein
the lift pin is configured to move up and down between a first height, a second height higher than the first height, and a third height higher than the second height,
while the lift pin moves between the first height and the second height, the lower ring is configured to stop moving and the upper ring is configured to move up and down, and
while the lift pin moves between the second height and the third height, the lower ring and the upper ring are configured to simultaneously move up and down.

3. The substrate processing apparatus of claim 2, wherein
when the lift pin is at a position lower than the first height, the lift pin is spaced apart from the upper ring and the lower ring,
when the lift pin moves between the first height and the second height, the lift pin contacts the upper ring, but the lower ring and the lift pin are spaced apart from each other, and
when the lift pin moves between the second height and the third height, the lift pin is configured to contact the upper ring and the lower ring.

4. The substrate processing apparatus of claim 1, wherein the lift pin includes three lift pins or more.

5. The substrate processing apparatus of claim 1, further comprising an outer ring configured to surround an outer circumference of the focus ring.

6. The substrate processing apparatus of claim 1, further comprising a guide block located on a circumference of the base so that the lift pin penetrates through the guide block to guide the movement of the lift pin.

7. The substrate processing apparatus of claim 1, wherein the upper ring and the lower ring include different materials from each other.

8. The substrate processing apparatus of claim 7, wherein the upper ring includes quartz, and the lower ring includes silicon carbide.

9. The substrate processing apparatus of claim 1, wherein the lift pin is configured to adjust the height of the upper ring so that the height of the upper surface of the upper ring and the height of the substrate are same.

10. A substrate processing apparatus comprising:
an electrostatic chuck disposed on a base to support a substrate;
a focus ring disposed on the base to surround an outer circumference of the electrostatic chuck; and
a lift pin configured to lift the focus ring,
wherein the focus ring includes a lower ring and an upper ring disposed on the lower ring, and
the upper ring is configured to be lifted or the upper ring and the lower ring are configured to be simultaneously lifted according to a height of the lift pin, and
the lower ring includes an insertion groove,
wherein the upper ring includes:
a main body unit;
a first protrusion extending downward from the main body unit and is inserted into the insertion groove of the lower ring; and
a second protrusion extending downward from the main body unit, contacting an outer circumference of the lower ring, and directly contacting the lift pin.

11. The substrate processing apparatus of claim 10, wherein
the lift pin is configured to move up and down between a first height, a second height higher than the first height, and a third height higher than the second height;
the lower ring is configured to stop moving and the upper ring is configured to move up and down when the lift pin moves between the first height and the second height; and
the lower ring and the upper ring are configured to be lifted simultaneously together when the lift pin moves between the second height and the third height.

12. The substrate processing apparatus of claim 11, wherein
when the lift pin is at a position lower than the first height, the lift pin is spaced apart from the upper ring and the lower ring,
when the lift pin moves between the first height and the second height, the lift pin contacts the upper ring, but the lower ring and the lift pin are spaced apart from each other, and
when the lift pin moves between the second height and the third height, the lift pin is configured to contact the upper ring and the lower ring.

13. The substrate processing apparatus of claim 10, wherein the lower ring includes:
a main body unit in which the insertion groove is formed; and
an outer unit extending outward from the main body unit of the lower ring and contacting the second protrusion of the upper ring, and
the lower ring is lifted by contacting the outer unit of the lower ring with the uppermost end of the lift pin.

14. The substrate processing apparatus of claim 10, wherein the main body unit of the lower ring is configured to be supported by contacting a circumferential groove formed on an outer circumference of the electrostatic chuck with the main body of the lower ring.

15. The substrate processing apparatus of claim 10, further comprising an outer ring, wherein the outer ring is configured to surround an outer circumference of the focus ring.

16. The substrate processing apparatus of claim 10, further comprising a guide block, wherein the guide block is located on a circumference of the base so that the lift pin penetrates through the guide block to guide the movement of the lift pin.

17. The substrate processing apparatus of claim 10, wherein the upper ring and the lower ring include different materials from each other.

18. The substrate processing apparatus of claim 10, wherein the lift pin is configured to adjust a height of the upper ring so that a height of an upper surface of the upper ring and a height of the substrate are same.

19. A substrate processing apparatus comprising:
an electrostatic chuck disposed on a base to support a substrate;
a focus ring disposed on the base to surround an outer circumference of the electrostatic chuck; and
a lift pin configured to lift the focus ring,
wherein the focus ring includes a lower ring and an upper ring disposed on the lower ring,
the upper ring is configured to be lifted or the upper ring and the lower ring are configured to be simultaneously lifted according to a height of the lift pin,
the lift pin is configured to move up and down between a first height, a second height higher than the first height, and a third height higher than the second height,
when the lift pin moves between the first height and the second height, the lower ring is configured to stop and the upper ring is configured to move up and down,
when the lift pin moves between the second height and the third height, the lower ring and the upper ring are configured to simultaneously move up and down,
when the lift pin is at a position lower than the first height, the lift pin is spaced apart from the upper ring and the lower ring,
wherein the lower ring includes:
a main body unit having an insertion groove; and
an outer unit extending outward from the main body unit and contacting a second protrusion of the upper ring,
wherein the upper ring includes:
a main body unit;
a first protrusion extending downward from the main body unit and inserted into the insertion groove of the lower ring; and
the second protrusion extending downward from the main body unit, contacting an outer circumference of the lower ring, and directly contacting the lift pin.

20. The substrate processing apparatus of claim 19, further comprising
an outer ring and a guide block,
wherein the outer ring is configured to surround an outer circumference of the focus ring,
the guide block is located on a circumference of the base so that the lift pin penetrates through the guide block to guide the movement of the lift pin, and
the upper ring includes quartz, and the lower ring includes silicon carbide.
